(19) United States
(12) Patent Application Publication
(10) Pub. No.: US 2011/0136317 A1
(43) Pub. Date: Jun. 9, 2011

(54) Semiconductor device, method of fabricating the same, and semicondutor module, electronic circuit board, and electronic system including the device

(75) Inventors: Sang-Yeol Kang, Seoul (KR); Youn-Soo Kim, Yongin-si (KR); Jae-Hyoung Choi, Hwaseong-si (KR); Jae-Soon Lim, Seoul (KR); Min-Young Park, Suwon-si (KR); Suk-Jin Chung, Hwaseong-si (KR)

(73) Assignee: Samsung Electronics Co., Ltd.

(21) Appl. No.: 12/659,830

(22) Filed: Mar. 23, 2010

(30) Foreign Application Priority Data
Dec. 7, 2009 (KR) 10-2009-0120778

(51) Int. Cl. H01L 21/02

(52) U.S. Cl. 438/396; 257/E21.01

(57) ABSTRACT

Example embodiments relate to a semiconductor device including an oxide dielectric layer and a non-oxide dielectric layer, a method of fabricating the device, and a semiconductor module, an electronic circuit board, and an electronic system including the device. The semiconductor device may include a lower electrode, an oxide dielectric layer disposed on the lower electrode, a non-oxide dielectric layer disposed on the oxide dielectric layer, and an upper electrode disposed on the non-oxide dielectric layer.

### CROSS-REFERENCE TO RELATED APPLICATION

This application claims priority under 35 U.S.C. §119 to Korean Patent Application No. 10-2009-0120778, filed on Dec. 7, 2009 with the Korean Intellectual Property Office, the entire contents of which are incorporated herein by reference.

### BACKGROUND

1. Field

Example embodiments relate to a semiconductor device including an oxide layer and a non-oxide layer, a method of fabricating the device, and a semiconductor module, an electronic circuit board, and an electronic system including the device.

2. Description of Related Art

Because of increases in integration density of semiconductor devices, a conventional dielectric layer having a relatively low dielectric constant and relatively large size and thickness may be problematic.

### SUMMARY

Example embodiments relate to a semiconductor device including an oxide dielectric layer and a non-oxide dielectric layer. Example embodiments also relate to a method of fabricating a semiconductor device including an oxide dielectric layer and a non-oxide dielectric layer. Example embodiments further relate to a semiconductor module, electronic circuit board, and electronic system including a semiconductor device having an oxide dielectric layer and a non-oxide dielectric layer.

A semiconductor device according to example embodiments may include a lower electrode; an oxide dielectric layer on the lower electrode; a non-oxide dielectric layer disposed on the oxide dielectric layer; and an upper electrode on the non-oxide dielectric layer.

Another semiconductor device according to example embodiments may include a lower electrode; a non-oxide dielectric layer on the lower electrode; an oxide dielectric layer on the non-oxide dielectric layer; and an upper electrode on the oxide dielectric layer.

Another semiconductor device according to example embodiments may include a lower electrode; a lowermost dielectric layer on the lower electrode; a lower dielectric layer on the lowermost dielectric layer; a main dielectric layer on the lower dielectric layer; a first upper dielectric layer on the main dielectric layer; a second upper dielectric layer on the first upper dielectric layer; an uppermost dielectric layer on the second upper dielectric layer; and an upper electrode on the uppermost dielectric layer.

Another semiconductor device according to example embodiments may include a semiconductor substrate; a gate on the semiconductor substrate; and a storage on the gate. The storage may include a lower electrode; an oxide dielectric layer on the lower electrode; a non-oxide dielectric layer on the oxide dielectric layer; and an upper electrode on the non-oxide dielectric layer.

Another semiconductor device according to example embodiments may include a semiconductor substrate; and a gate on the semiconductor substrate. The gate may include a lower electrode; an oxide dielectric layer on the lower electrode; a non-oxide dielectric layer on the oxide dielectric layer; and an upper electrode on the non-oxide dielectric layer.

A method of fabricating a semiconductor device may include forming a lower electrode; forming an oxide dielectric layer on the lower electrode; forming a non-oxide dielectric layer on the oxide dielectric layer; and forming an upper electrode on the non-oxide dielectric layer.

Another method of fabricating a semiconductor device may include loading a wafer into a reaction chamber; performing a first process to form an oxide dielectric layer on the wafer; and performing a second process to form a non-oxide dielectric layer on the oxide dielectric layer. The first process may include supplying a first precursor to the reaction chamber to form a first unit dielectric layer on the wafer; supplying a first purge gas to the reaction chamber to discharge any remaining first precursor from the reaction chamber; supplying an oxidizer to the reaction chamber to convert the first unit dielectric layer into a unit oxide dielectric layer; an supplying a second purge gas to the reaction chamber to discharge any remaining oxidizer from the reaction chamber. Supplying the first precursor, supplying the first purge gas, supplying the oxidizer, and supplying the second purge gas may constitute a first cycle. The first cycle may be repeated a plurality of times. The second process may include supplying a second precursor to the reaction chamber to form a second unit dielectric layer on the oxide dielectric layer; and supplying a third purge gas to the reaction chamber to discharge any remaining second precursor from the reaction chamber. Supplying the second precursor and supplying the third purge gas may constitute a second cycle. The second cycle may be repeated a plurality of times.

Another method of fabricating a semiconductor device according to example embodiments may include forming a lowermost dielectric layer; forming a lower dielectric layer on the lowermost dielectric layer; forming a main dielectric layer on the lower dielectric layer; forming a first upper dielectric layer on the main dielectric layer; forming a second upper dielectric layer on the first upper dielectric layer; and forming an upper electrode on the second upper dielectric layer, wherein each of the lowermost dielectric layer, the lower dielectric layer, the first upper dielectric layer, and the second upper dielectric layer may include a first metal.

A semiconductor module according to example embodiments may include a module substrate; a plurality of semiconductor devices on the module substrate; and module contact terminals on an edge of the module substrate and electrically connected to the semiconductor devices. At least one of the plurality of semiconductor devices may include a lower electrode; an oxide dielectric layer on the lower electrode; a non-oxide dielectric layer on the oxide dielectric layer; and an upper electrode on the non-oxide dielectric layer.

An electronic system according to example embodiments may include a control unit; an input unit; an output unit; and a storage unit. At least one of the control unit, the input unit, the output unit, and the storage unit may include a lower electrode; an oxide dielectric layer on the lower electrode; a non-oxide dielectric layer on the oxide dielectric layer; and an upper electrode on the non-oxide dielectric layer.

### BRIEF DESCRIPTION OF THE DRAWINGS

Example embodiments are described in further detail below with reference to the accompanying drawings. It should be understood that various aspects of the drawings may have been exaggerated for clarity.

FIGS. 1A through 1C are conceptual diagrams of capacitors that may be included in a semiconductor device according to example embodiments.

FIGS. 2A through 2C are flowcharts illustrating methods of forming capacitors that may be included in a semiconductor device according to example embodiments.

FIG. 3 is a schematic diagram of a process apparatus that may be used in a method of forming a capacitor included in a semiconductor device according to example embodiments.

FIGS. 4 through 7 are schematic diagrams illustrating a method of forming a capacitor that may be included in a semiconductor device according to example embodiments.

FIGS. 8A through 8C are cross-sectional views illustrating another method of forming a capacitor that may be included in a semiconductor device according to example embodiments.

FIGS. 9A through 9D are cross-sectional views illustrating another method of forming a capacitor that may be included in a semiconductor device according to example embodiments.

FIG. 10 is a cross-sectional view of a semiconductor device including an oxide dielectric layer and a non-oxide dielectric layer as a base material according to example embodiments.

FIGS. 11A and 11B are cross-sectional views of semiconductor devices including dielectric layers according to example embodiments.

FIG. 12A is a schematic view of a semiconductor module including a semiconductor device having an oxide dielectric layer and a non-oxide dielectric layer according to example embodiments.

FIG. 12B is a block diagram of an electronic circuit board including a semiconductor device having an oxide dielectric layer and a non-oxide dielectric layer according to example embodiments.

FIG. 12C is a block diagram of an electronic system including a semiconductor device or semiconductor module having an oxide dielectric layer and a non-oxide dielectric layer according to example embodiments.

FIG. 13 is a graph illustrating secondary ion mass spectrometry (SIMS) measurements plotted on a log scale of a depth profile of chlorine (Cl) in a capacitor included in a semiconductor device having only an oxide dielectric layer and a depth profile of Cl in a capacitor included in a semiconductor device having both an oxide dielectric layer and a non-oxide dielectric layer according to example embodiments.

FIGS. 14(a)-(b) are graphs showing results of a leakage sweep test of a capacitor included in a semiconductor device including only an oxide dielectric layer and a capacitor included in a semiconductor device including both an oxide dielectric layer and a non-oxide dielectric layer according to example embodiments.

FIG. 15 is a graph showing results of an operation test of a capacitor included in a semiconductor device including only an oxide dielectric layer and a capacitor included in a semiconductor device including both an oxide dielectric layer and a non-oxide dielectric layer according to example embodiments.

### DETAILED DESCRIPTION

Example embodiments will now be described more fully with reference to the accompanying drawings. However, it should be understood that the present inventive concept may be embodied in different forms and should not be construed as limited to the examples set forth herein. In the drawings, the thicknesses of layers and regions may have been exaggerated for clarity. Like numbers refer to like elements throughout.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms, “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to drawings that may be illustrations of idealized embodiments of the present inventive concept. As such, variations from the shapes of the illustrations as a result, for example, of manufacturing techniques and/or tolerances, are to be expected. Thus, embodiments of the present inventive concept should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present inventive concept.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the specification, the term “non-oxide” should be not be interpreted as having absolutely no oxygen (O), but rather, as being formed without a supply of oxygen or an oxidation process. A supply of oxygen or an oxidation process should be understood to mean a deliberate supply or process that involves more than a passive exposure to the atmosphere. Because the atmosphere contains a relatively large amount of oxygen, it is actually impossible to form a completely oxygen-free material. Also, even a non-oxide material may contain oxygen atoms when it is formed adjacent to an oxide material layer. Stated more clearly, any non-oxide material will contain some oxygen according to the surrounding atmospheric conditions and material compositions. For this reason, oxygen may still be detected in the analysis of a non-oxide material. Therefore, according to the present inventive concept, a non-oxide material should be understood to be material formed without supplying an oxidizer.

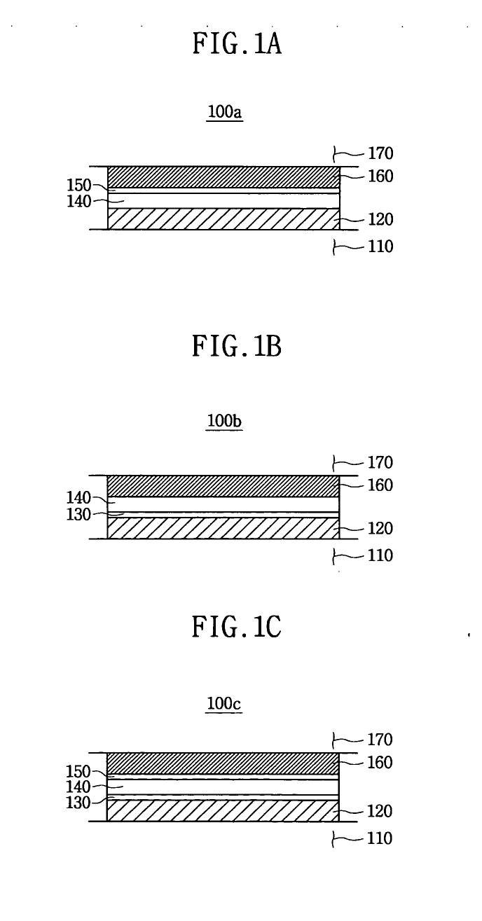

FIGS. 1A through 1C are conceptual diagrams of capacitors that may be included in a semiconductor device according to example embodiments. Referring to FIG. 1A, a capacitor 100a included in a semiconductor device according to example embodiments may include a lower electrode 120, an oxide dielectric layer 140 disposed on the lower electrode 120, an upper non-oxide dielectric layer 150 disposed on the oxide dielectric layer 140, and an upper electrode 160 disposed on the upper non-oxide dielectric layer 150.

Referring to FIG. 1B, a capacitor 100b included in a semiconductor device according to example embodiments may include a lower electrode 120, a lower non-oxide dielectric layer 130 disposed on the lower electrode 120, an oxide dielectric layer 140 disposed on the lower non-oxide dielectric layer 130, and an upper electrode 160 disposed on the oxide dielectric layer 140.

Referring to FIG. 1C, a capacitor 100c included in a semiconductor device according to example embodiments may include a lower electrode 120, a lower non-oxide dielectric layer 130 disposed on the lower electrode 120, an oxide dielectric layer 140 disposed on the lower non-oxide dielectric layer 130, an upper non-oxide dielectric layer 150 disposed on the oxide dielectric layer 140, and an upper electrode 160 disposed on the upper non-oxide dielectric layer 150.

Referring to FIGS. 1A through 1C, each of the capacitors 100a to 100c may be disposed between a lower layer 110 and an upper layer 170. The lower layer 110 may be a semiconductor substrate, a lower interlayer insulating layer, a lower capping layer, a lower conductive interconnection, or a lower via plug. The upper layer 170 may be an upper interlayer insulating layer, an upper capping layer, an upper conductive interconnection, an upper via plug, or a passivation layer. The lower electrode 120 may be formed of a conductive material, e.g., silicon, a metal, a metal silicide, a metal compound, or a metal alloy. The oxide dielectric layer 140 may include oxygen (O). Examples of various types of base materials for the oxide dielectric layer 140 will be described later.

Each of the lower non-oxide dielectric layer 130 and the upper non-oxide dielectric layer 150 may include at least one element selected from the group consisting of hydrogen (H), boron (B), carbon (C), nitrogen (N), fluorine (F), chlorine (Cl), and iodine (I). The lower non-oxide dielectric layer 130 and the upper non-oxide dielectric layer 150 may include at least one of the base materials of the oxide dielectric layer 140. Stated more clearly, the lower non-oxide dielectric layer 130 and the upper non-oxide dielectric layer 150 may include various materials, for example, the same base material or different base materials as will be described in detail later. The upper electrode 160 may be formed of a conductive material, e.g., a metal, a metal silicide, a metal compound, or a metal alloy.

Referring to FIGS. 1A through 1C, the lower non-oxide dielectric layer 130 may protect the lower electrode 120 from the reactive materials (e.g., radicals) used to form the oxide dielectric layer 140 during the formation of the capacitors 100a to 100c. For example, the lower non-oxide dielectric layer 130 may protect the lower electrode 120 from oxygen radicals (O⁻). When the lower electrode 120 is formed and the oxide dielectric layer 140 is formed on the lower electrode 120, oxygen radicals may react with the lower electrode 120 such that the surface of the lower electrode 120 may be oxidized. When the lower electrode 120 is oxidized, the resistance of the lower electrode 120 may be partially or wholly increased. This is because the surface of the lower electrode 120 may be changed into a relatively highly resistant insulating material as a result of the oxidation reaction. That being said, the lower electrode 120 may be formed of a conductive material having a lower resistance to obtain better characteristics.

The lower non-oxide dielectric layer 130 may be formed of a material that can react with the oxide dielectric layer 140, for example, the same metal as a metal forming the oxide dielectric layer 140. In some cases, the lower non-oxide dielectric layer 130 may be absorbed into a portion of the oxide dielectric layer 140. Stated more clearly, a portion of the lower non-oxide dielectric layer 130 may react with oxygen radicals and be oxidized. Thus, characteristics (e.g., material, composition ratio, and thickness) of the lower non-oxide dielectric layer 130 may be variously controlled. For example, when it is intended to completely prevent the lower electrode 120 from reacting with oxygen radicals, the lower non-oxide dielectric layer 130 may be formed to a sufficient thickness. In another case, when the lower electrode 120 is not particularly reactive with oxygen radicals such that contact between the lower electrode 120 and oxygen radicals is not considered a serious problem, the lower non-oxide dielectric layer 130 may be formed to a reduced or minimum thickness. When the lower electrode 120 has a relatively high tolerance to oxygen radicals, the lower non-oxide dielectric layer 130 may be omitted as will be described later with reference to subsequent example embodiments. The upper non-oxide dielectric layer 150 may protect the oxide dielectric layer 140 from reactive materials (e.g., radicals) used to form the upper electrode 160.

The oxide dielectric layer 140 may be regarded as a relatively important component in determining the capacitance of the capacitors 100a to 100c. Therefore, process parameters for forming the oxide dielectric layer 140 should be controlled with relative precision. However, when reactive radicals react with the oxide dielectric layer 140 during the formation of the upper electrode 160, the material organization of the oxide dielectric layer 140 may be adversely affected or destroyed, or the chemical composition, physical properties, or dielectric constant of the oxide dielectric layer 140 may be changed. Accordingly, it may be beneficial to protect the oxide dielectric layer 140 during the formation of the upper electrode 160.

Radicals used during the formation of the upper electrode 160 may mildly attack the oxide dielectric layer 140. However, as semiconductor devices have become ultra-highly integrated, the characteristics of the oxide dielectric layer 140 may be relatively sensitive even to slight changes. Therefore, finding a technique of safely protecting the oxide dielectric layer 140 from a process of forming the upper electrode 160 may need to be addressed. For example, when the upper electrode 160 is formed of titanium nitride, hydrochloric acid (HCl) is generated during the formation of the upper electrode 160 (TiCl₄+NH₃=TiN+HCl, (H₂)). In this process, protecting the oxide dielectric layer 140 from Cl radicals (Cl⁻) is an important issue. Also, the Cl radicals may diffuse and move toward the lower electrode 120 along grain boundaries formed within the oxide dielectric layer 140. Because the oxide dielectric layer 140 has a relatively small thickness of several tens to several hundreds of Å, the influence of the Cl radicals on the lower electrode 120 may be greater than expected. Accordingly, it is important to protect the oxide dielectric layer 140 from reactive radicals generated during the formation of the upper electrode 160 on the oxide dielectric layer 140.

The base material of the oxide dielectric layer 140, the lower non-oxide dielectric layer 130, and the upper non-oxide dielectric layer 150 may include at least one element selected from the group consisting of lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), cesium (Cs), barium (Ba), lanthanum (La), hafnium (Hf), tantalum (Ta), tungsten (W), rhenium (Re), osmium (Os), iridium (Ir), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), platinum (Pt), gold (Au), mercury (Hg), lead (Pb), bismuth (Bi), polonium (Po), francium (Fr), radium (Ra), actinium (Ac), and silicon (Si).

Stated more clearly, the oxide dielectric layer 140 may include oxygen and at least one of the above-described materials. Each of the lower non-oxide dielectric layer 130 and the upper non-oxide dielectric layer 150 may include at least one of the above-described materials and at least one element selected from the group consisting of hydrogen (H), boron (B), carbon (C), nitrogen (N), fluorine (F), chlorine (Cl), and iodine (I) as well as trace amounts of oxygen (O). According to the present inventive concept, each of the oxide dielectric layer 140, the lower non-oxide dielectric layer 130, and the upper non-oxide dielectric layer 150 may include a metal as a base material. For example, the oxide dielectric layer 140 may be a metal-oxide dielectric layer, and each of the lower non-oxide dielectric layer 130 and the upper non-oxide dielectric layer 150 may be a metal-non-oxide dielectric layer. The upper non-oxide dielectric layer 140 may be formed to a thickness of about 100 Å or less. According to experimental results, desired effects may be expected when the upper non-oxide dielectric layer 140 is formed to a thickness of about 100 Å or less.

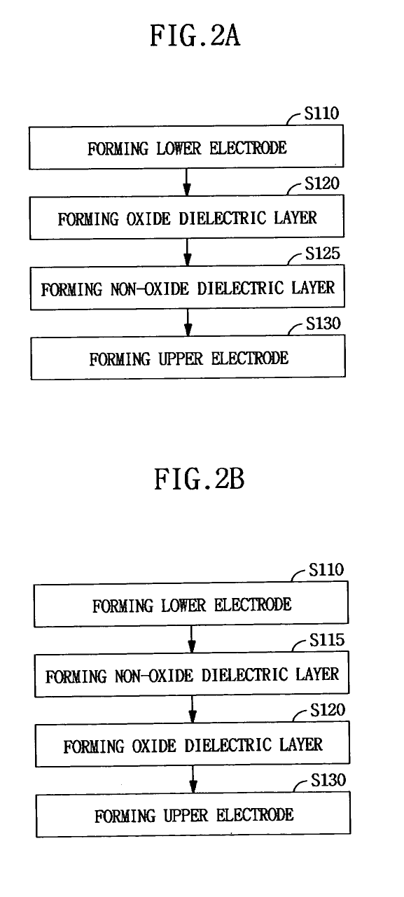

FIGS. 2A through 2C are flowcharts illustrating methods of forming capacitors that may be included in a semiconductor device according to example embodiments. Referring to FIG. 2A, a method of forming a capacitor included in a semiconductor device may include forming a lower electrode (S110), forming an oxide dielectric layer (S120), forming an upper non-oxide dielectric layer (S125), and forming an upper electrode (S130).

Referring to FIG. 2B, a method of forming a capacitor included in a semiconductor device may include forming a lower electrode (S110), forming a lower non-oxide dielectric layer (S115), forming an oxide dielectric layer (S120), and forming an upper electrode (S130).

Referring to FIG. 2C, a method of forming a capacitor included in a semiconductor device may include forming a lower electrode (S110), forming a lower non-oxide dielectric layer (S115), forming an oxide dielectric layer (S120), forming an upper non-oxide dielectric layer (S125), and forming an upper electrode (S130).

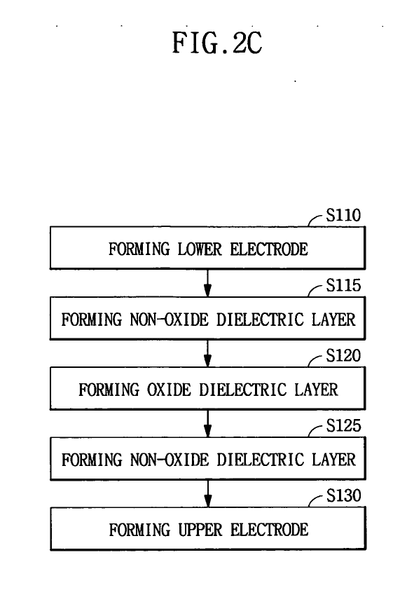

FIG. 3 is a schematic diagram of a process apparatus that may be used in a method of forming a capacitor included in a semiconductor device according to example embodiments. Referring to FIG. 3, a process apparatus 200 may include a storage tank 210 and a reaction chamber 220. The storage tank 210 may include a carrier gas inlet pipe 213 and a source outlet pipe 217. The reaction chamber 220 may include a wafer chuck 230, a source supply pipe 240, a purge gas supply pipe 250, an oxidizer supply pipe 260, and an exhaust pipe 270. A source material S may be stored in the storage tank 210. The source material S stored in the storage tank 210 may be heated to an appropriate temperature, for example, a temperature below the boiling point. A method of forming a capacitor using the process apparatus 200 will be described in detail later.

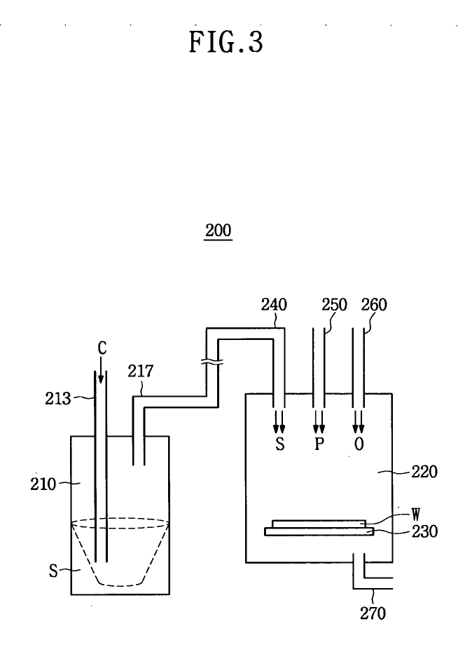

FIGS. 4 through 7 are schematic diagrams illustrating a method of forming a capacitor that may be included in a semiconductor device according to example embodiments. FIGS. 4, 5A, 6A, and 7 are cross-sectional views illustrating processes of forming respective material layers, and FIGS. 5B and 6B illustrate process recipes. In FIGS. 5B and 6B, an abscissa (x axis) denotes a time, and an ordinate (y axis) denotes the supply of respective materials or gases. Referring to FIG. 4, a lower electrode 120 may be formed on a lower layer 110. The lower electrode 120 may be formed of titanium nitride, although other suitable conductive materials may be used. A method of forming the lower electrode 120 will be described later. The lower layer 110 may be a semiconductor substrate, a lower interlayer insulating layer, a lower capping layer, a lower conductive interconnection, or a lower via plug. The lower electrode 120 may be formed using a deposition process, a patterning process, a filling process, or a plating process. Although the lower electrode 120 is illustrated as not being patterned, example embodiments are not limited thereto.

Referring to FIGS. 3, 5A, and 5B, an oxide dielectric layer 140 may be formed on the lower electrode 120. The oxide dielectric layer 140 may undergo a plurality of process cycles Ca1, Ca2, and Ca3. In a first operation Sa1 of the first cycle Ca1, a source material S may be supplied to the reaction chamber 220. The source material S may refer to a compound containing materials of the oxide dielectric layer 140 other than oxygen. The source material S may be, for example, a zinc (Zn)-containing metal organic compound. The Zn-containing metal organic compound may be tetrakis[ethylmethylamino]zirconium (TEMAZ) or Zr[N(CH₃)(C₂H₅)]₄). A carrier gas C may be injected through the carrier gas inlet pipe 213 into the storage tank 210 containing the source material S (e.g., TEMAZ). The TEMAZ source material S may be heated to a temperature below the boiling point. An inert gas (e.g., Ar gas) may be used as the carrier gas C. The TEMAZ source material S may be evaporated along with the carrier gas C and supplied from the storage tank 210 to the reaction chamber 220. The TEMAZ source material S supplied to the reaction chamber 220 may be in such a state as to deposit a material layer on the wafer W in a precursor state. The inside of the reaction chamber 220 may maintain a vacuum state. A unit dielectric layer may be formed in order to form the oxide dielectric layer 140 on the lower electrode 120. The unit dielectric layer may be in an unoxidized state and may have a composition of ZrCₓ, ZrN_{y}, ZrCₓN_{y}, ZrCH, ZrNH, or ZrCₓN_{y}H, wherein x may be greater than 0, and y may be smaller than 2. Also, the oxide dielectric layer 140 may include a relatively small amount of H.

In a second operation Sa2 of the first cycle Ca1, a purge gas P may be supplied to the reaction chamber 220, thereby purging the inside of the reaction chamber 220. During purging, the supply of the source material S to the reaction chamber 220 may be interrupted. As a result, the source material S may be discharged out of the reaction chamber 220 by the purge gas P.

In a third operation Sa3 of the first cycle Ca1, an oxidizer O may be supplied to the reaction chamber 220. The oxidizer O may be supplied in a gas state. The oxidizer O may oxidize the unit dielectric layer. When the unit dielectric layer is not formed to a relatively great thickness or the third operation Sa3 is performed for a sufficient amount of time, the oxidizer O may completely oxidize the unit dielectric layer to form a unit oxide dielectric layer. The oxidizer O may be ozone (O₃), oxygen (O₂), water vapor (H₂O), or nitrous oxide (N₂O). For example, the oxidizer O may be O₂ plasma.

In a fourth operation Sa4 of the first cycle Ca1, the supply of the oxidizer O may be interrupted, and the purge gas P may be supplied. The process operation Sa4 may discharge the remaining oxidizer O from the reaction chamber 220. It should be understood that the description of the process operations is provided under the assumption that the oxide dielectric layer 140 is formed using an atomic layer deposition (ALD) process, although example embodiments are not limited thereof. The ALD process involves repeating a cycle including a plurality of unit processes, which are sequentially performed, to form a material layer.

The first through fourth operations Sa1 through Sa4 may constitute one cycle Ca1. The cycle Ca1 may be repeated a plurality of times. When the formation of the oxide dielectric layer 140 is performed using a chemical vapor deposition (CVD) process instead of the ALD process, the cycles Ca1 through Ca3 may not be needed. Stated more clearly, a process of supplying the source material S and a process of supplying the oxidizer O may be performed simultaneously. Also, when the oxide dielectric layer 140 includes materials other than Zn and is formed without the process apparatus 200 and process of FIG. 3, the oxide dielectric layer 140 may be formed using another method. For instance, the carrier gas C may not be employed, and an additional apparatus for evaporating the liquid-state source material S may not be used but replaced by an evaporation apparatus using a different mode.

Referring to FIGS. 3, 6A, and 6B, an upper non-oxide dielectric layer 150 may be formed on the oxide dielectric layer 140. The upper non-oxide dielectric layer 150 may undergo a plurality of process cycles Cb1, Cb2, Cb3, and Cb4. In a first operation Sb1 of the first cycle Cb1, a source material S may be supplied to the reaction chamber 220. For purposes of brevity, the same source material S as described above may be used. In a second operation Sb2 of the first cycle Cb1, a purge gas P may be supplied to the reaction chamber 220, thereby purging the inside of the reaction chamber 220. As a result, the supply of the source material S to the reaction chamber 220 may be interrupted. In the second operation Sb2, the source material S may be discharged out of the reaction chamber 220. The process operations Sb1 to Sb2 may constitute one cycle Cb1. The cycle Cb1 may be repeated a plurality of times, for example, several to several tens of times. The upper non-oxide dielectric layer 150 may be formed using a CVD process. The upper non-oxide dielectric layer 150 may be annealed at room temperature to a temperature of about 800° C. or lower for several tens of seconds. The annealing process may be performed in an atmosphere containing at least one of inert gases, including hydrogen (H₂), oxygen (O₂), ammonia (NH₃), nitrous oxide (N₂O), nitrogen (N₂), ozone (O₃), and/or argon (Ar). Alternatively, the annealing process may be performed in a plasma atmosphere using the above-described materials.

Referring to FIGS. 3 and 7, an upper electrode 160 may be formed on the upper non-oxide dielectric layer 150. The upper electrode 160 may be formed of the same material as the lower electrode 120, for example, titanium nitride (TiN), although other suitable conductive materials may be used. As described above, the TiN upper electrode 160 may be formed by reaction of titanium tetrachloride (TiCl₄) with ammonia (NH₃). Hydrogen (H), chlorine (Cl), and hydrochloric acid (HCl) may be generated as by-products. The upper non-oxide dielectric layer 150 may effectively prevent the by-products from moving or permeating into the oxide dielectric layer 140 and the lower electrode 120. For example, when the by-products are reactive, the upper non-oxide dielectric layer 150 may react with the by-products, thereby hindering or preventing the by-products from moving or penetrating into the oxide dielectric layer 140 and the lower electrode 120. An upper layer 170 may be formed on the upper electrode 160. The upper layer 170 may be an upper interlayer insulating layer, an upper capping layer, an upper conductive interconnection, an upper via plug, or a passivation layer. In order to complete the capacitor, the lower electrode 120, the oxide dielectric layer 140, the upper non-oxide dielectric layer 150, and the upper electrode 160 may be patterned after forming the lower electrode 120 or after forming the upper electrode 160.

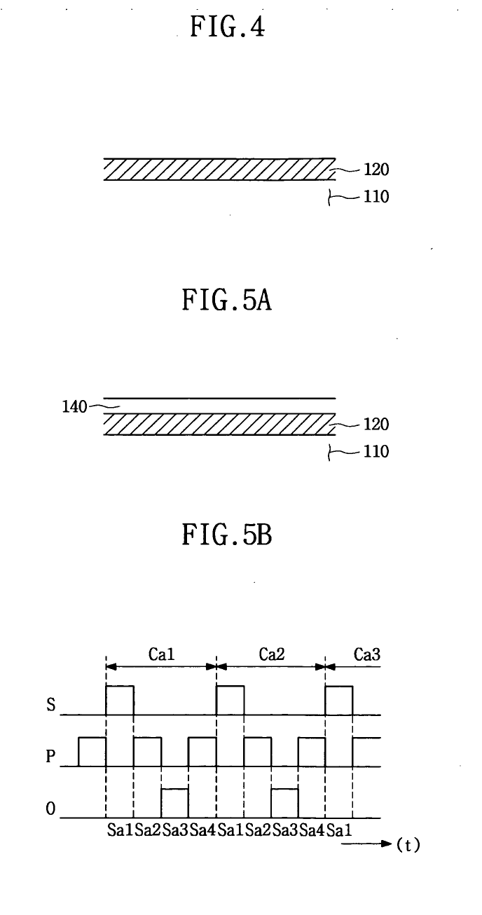

FIGS. 8A through 8C are cross-sectional views illustrating another method of forming a capacitor that may be included in a semiconductor device according to example embodiments. Referring to FIG. 8A, a lower electrode 120 may be formed on a lower layer 110, and a lower non-oxide dielectric layer 130 may be formed on the lower electrode 120. A process of forming the lower non-oxide dielectric layer 130 may be as described above with reference to FIGS. 3, 6A, and 6B. Referring to FIG. 8B, an oxide dielectric layer 140 may be formed on the lower non-oxide dielectric layer 130. A process of forming the oxide dielectric layer 140 may be as described above with reference to FIGS. 3, 5A, and 5B. The lower non-oxide dielectric layer 130 may protect the lower electrode 120 from oxygen radicals. For example, the lower non-oxide dielectric layer 130 may react with an oxidizer supplied during the formation of the oxide dielectric layer 140, thereby hindering or preventing the oxidizer from permeating into the lower electrode 120. Thus, although not shown in FIGS. 8A-8C, when the entire lower non-oxide dielectric layer 130 reacts with the oxidizer, the lower non-oxide dielectric layer 130 may be completely consumed. Referring to FIG. 8C, an upper electrode 160 may be formed on the oxide dielectric layer 140. An upper layer 170 may be formed on the upper electrode 160.

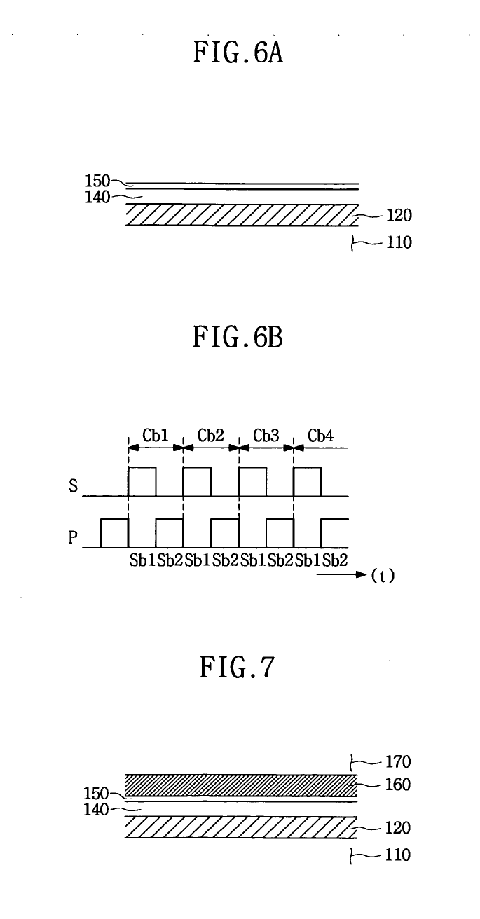

FIGS. 9A through 9D are cross-sectional views illustrating another method of forming a capacitor that may be included in a semiconductor device according to example embodiments. Referring to FIG. 9A, a lower electrode 120 may be formed on the lower layer 110, and a lower non-oxide dielectric layer 130 may be formed on the lower electrode 120. Referring to FIG. 9B, an oxide dielectric layer 140 may be formed on the lower non-oxide dielectric layer 130. Referring to FIG. 9C, an upper non-oxide dielectric layer 150 may be formed on the oxide dielectric layer 440. Referring to FIG. 9D, an upper electrode 160 may be formed on the upper non-oxide dielectric layer 150. An upper layer 170 may be formed on the upper electrode 160.

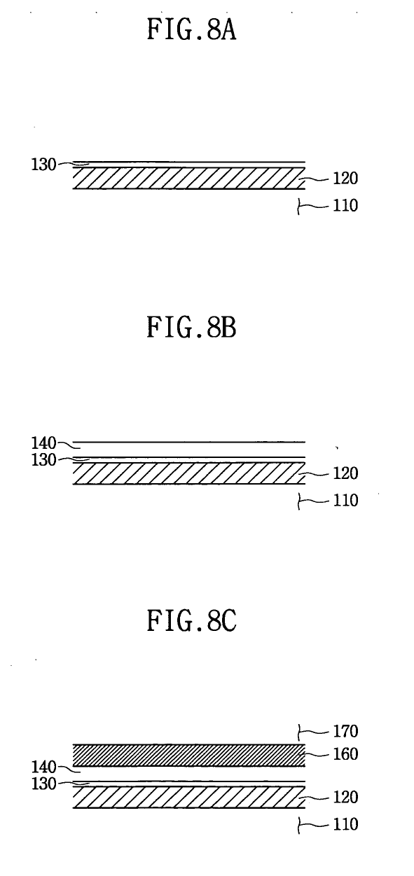

FIG. 10 is a cross-sectional view of a semiconductor device including an oxide dielectric layer and a non-oxide dielectric layer as a base material according to example embodiments. In addition, FIG. 10 shows an example case where all lower non-oxide material layers may be oxidized. Referring to FIG. 10, the semiconductor device may include a lower electrode 320 disposed on a lower layer 310, a lowermost dielectric layer 330 disposed on the lower electrode 320, a lower dielectric layer 340 disposed on the lowermost dielectric layer 330, a main dielectric layer 350 disposed on the lower dielectric layer 340, a first upper dielectric layer 360 disposed on the main dielectric layer 350, a second upper dielectric layer 370 disposed on the first upper dielectric layer 360, an uppermost dielectric layer 380 disposed on the second upper dielectric layer 370, and an upper electrode 390 disposed on the uppermost dielectric layer 380.

It should be understood that one or more of the above-discussed materials may be used in connection with the semiconductor device of FIG. 10. For example, the lower electrode 320 and the upper electrode 390 may be formed of titanium nitride (TiN). The main dielectric layer 350 may correspond to an oxide dielectric layer or a metal oxide dielectric layer. The main dielectric layer 350 may be a tantalum oxide (TaO) layer. The remaining dielectric layers 330, 340, 360, 370, and 380 may be non-oxide dielectric layers. The lowermost dielectric layer 330 may be formed as described above with reference to FIGS. 6A and 6B. Stated more clearly, the lowermost dielectric layer 330 may be formed using a method of forming a non-oxide dielectric layer. However, it should be understood that the lowermost dielectric layer 330 may be oxidized during the formation of the lower dielectric layer 340 or the formation of the main dielectric layer 350. For example, a ZrC layer, a ZrN layer, or a ZrCN layer may be formed and oxidized so that a lowermost dielectric layer 330 formed of ZrO, ZrCO, ZrON, or ZrCON may be obtained. The lower dielectric layer 340 may be formed as described above with reference to FIGS. 6A and 6B. Stated more clearly, the lower dielectric layer 340 may be formed using a method of forming a non-oxide dielectric layer.

The lower dielectric layer 340 and the lowermost dielectric layer 330 may be material layers formed simultaneously. For example, a single material layer may be formed and separated into the lower dielectric layer 340 and the lowermost dielectric layer 330 by a chemical reaction. For example, a non-oxide dielectric layer may be formed and oxidized during the formation of the main dielectric layer 350 or chemically reacted with a base material of the main dielectric layer 350 so that the non-oxide dielectric layer can be separated into the lowermost dielectric layer 330 and the lower dielectric layer 340. In addition, the lowermost dielectric layer 330 and the lower dielectric layer 340 may suffer analog elemental changes. The lower dielectric layer 340 may include a combination of a material of the lowermost dielectric layer 330 and tantalum (Ta), which may be a base material of the main dielectric layer 350. The lower dielectric layer 340 may be formed of, for example, ZrTaO, ZrTaCO, ZrTaON, or ZrTaCON.

The main dielectric layer 350 may be formed as described above with reference to FIGS. 5A and 5B. The main dielectric layer 350 may be formed of Ta as a base material, although example embodiments are not limited thereto. For example, the main dielectric layer 350 may be formed of tantalum oxide (TaO), and a source material used during the formation of the TaO main dielectric layer 350 may be a Ta-containing material. Because a method of forming a TaO layer is well known to one ordinarily skilled in the art, a description thereof will be omitted for purposes of brevity.

The first upper dielectric layer 360 may be formed as described above with reference to FIGS. 6A and 6B. The first upper dielectric layer 360 may have a composition that is the same as or similar to the lower dielectric layer 340. This is because the first upper dielectric layer 360 may chemically react with oxygen and/or a base material of the main dielectric layer 350. For instance, the first upper dielectric layer 360 may be formed of ZrTaO, ZrTaCO, ZrTaON, or ZrTaCON. The second upper dielectric layer 370 may be formed as described above with reference to FIGS. 6A and 6B. Stated more clearly, the second upper dielectric layer 370 may be formed using a method of forming a non-oxide dielectric layer. The second oxide dielectric layer 370 may be formed simultaneously with the first upper dielectric layer 360. For example, after the second oxide dielectric layer 370 is formed simultaneously with the first upper dielectric layer 360, the second oxide dielectric layer 370 may react with materials of the main dielectric layer 350 and separate into two layers. The formation of the second oxide dielectric layer 370 may include forming a non-oxide dielectric layer and causing a chemical reaction of the non-oxide dielectric layer with oxygen or the base material of the main dielectric layer 350. The second oxide dielectric layer 370 may include the base material of the main dielectric layer 350. The second upper dielectric layer 370 may be free from the oxygen of the main dielectric layer 350 or, alternatively, may include only a negligible amount of the oxygen. For example, the second upper dielectric layer 370 may be formed of ZrTaC, ZrTaN, or ZrTaCN. Furthermore, the first and second upper dielectric layers 360 and 370 may suffer analog elemental changes.

The uppermost dielectric layer 380 may be formed as described above with reference to FIGS. 6A and 6B. Stated more clearly, the uppermost dielectric layer 380 may be formed using a method of forming a non-oxide dielectric layer. The uppermost dielectric layer 380 may be a material layer formed simultaneously with the first upper dielectric layer 360 and/or the second upper dielectric layer 370. For example, after the uppermost dielectric layer 380 is formed simultaneously with the first dielectric layer 360 and/or the second upper dielectric layer 370, materials of the main dielectric layer 350 may chemically react with the first and second upper dielectric layers 360 and 370, but not with the uppermost dielectric layer 380. Thus, the uppermost dielectric layer 380 may remain the same as an initially formed non-oxide dielectric layer. The uppermost dielectric layer 380 may be a layer formed of ZrC, ZrN, or ZrCN.

The layers may have various thicknesses and may be as follows with regard to increasing thickness: the first upper dielectric layer 360, the lower dielectric layer 340, the second upper dielectric layer 370, the uppermost dielectric layer 380, and the lowermost dielectric layer 330. For example, the first upper dielectric layer 360 may be formed to a thickness of about 10 Å, the lower dielectric layer 340 may be formed to a thickness of about 24 Å, the second upper dielectric layer 370 may be formed to a thickness of about 28 Å, the uppermost dielectric layer 380 may be formed to a thickness of about 34 Å, the lowermost dielectric layer 330 may be formed to a thickness of about 34 Å, and the main dielectric layer 350 may be formed to a thickness of about 58 Å. The material layers 330, 340, 350, 360, 370, and 380 may have different absolute and relative thicknesses or may not be present depending on process conditions. However, elements of the respective material layers 330 to 380 may be mapped using an electron energy loss spectroscopy (EELS) mapping technique.

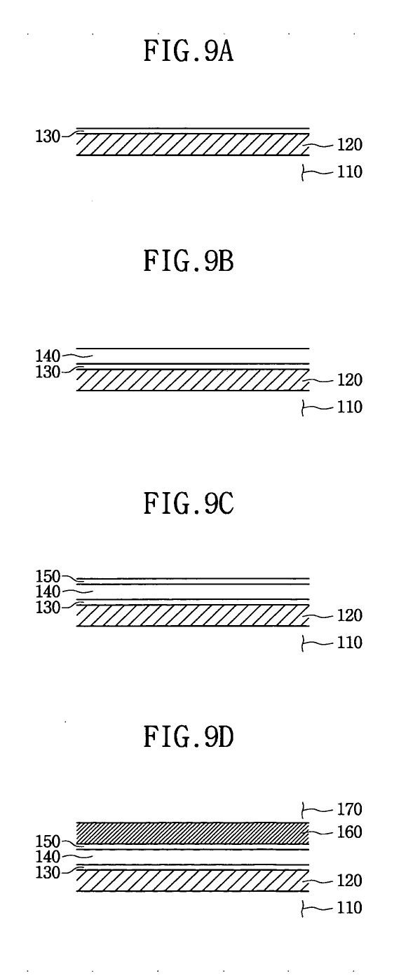

FIGS. 11A and 11B are cross-sectional views of semiconductor devices including dielectric layers according to example embodiments. The semiconductor device of FIG. 11A may be interpreted as a dynamic random access memory (DRAM) semiconductor device, while the semiconductor device of FIG. 11B may be interpreted as a flash memory device. Referring to FIG. 11A, a semiconductor device 400 according to example embodiments may include a semiconductor substrate 405, isolation regions 410, gates 415, a first interlayer insulating layer 420, a bit line contact 425, a bit line 430, a second interlayer insulating layer 435, a storage contact 440, and a storage 450. The storage 450 may include a storage electrode 460, a storage dielectric layer 470, and a plate electrode 480. The storage dielectric layer 470 may include an oxide dielectric layer and a non-oxide dielectric layer. The oxide dielectric layer and the non-oxide dielectric layer may be as described with reference to the above examples. The structures and functions of unmentioned components may be such so as to already be well understood by one skilled in the art. In consideration of only the shape of the storage 450, the semiconductor device 400 may be interpreted as a logic semiconductor device including a metal-insulator-metal (MIM) capacitor, a static RAM (SRAM) semiconductor device, a flash memory device, a resistive RAM (RRAM), a phase-change RAM (PRAM), a magnetic semiconductor device, or other appropriate semiconductor device.

Referring to FIG. 11B, a semiconductor device 500 according to example embodiments may include a plurality of gates 510 disposed on a semiconductor substrate 505. The gates 510 may include a gate insulating layer 520, a lower gate electrode 530, an inter-gate dielectric layer 540, and an upper gate electrode 550. The inter-gate dielectric layer 540 may include an oxide dielectric layer and a non-oxide dielectric layer as described with reference to the above examples. The lower gate electrode 530 and the upper gate electrode 550 may be understood to be components similar to the above-described lower and upper electrodes, respectively. The lower gate electrode 530 may be a floating gate electrode, and the upper gate electrode 550 may be a control gate electrode. Alternatively, when the semiconductor device 500 is a charge-trap-flash (CTF) device, the semiconductor device 500 may include a CTF structure 560 illustrated in a left portion of FIG. 11B. The CTF structure 560 may include a CTF dielectric layer 570 and a gate electrode 580. The CTF dielectric layer 570 may include an oxide dielectric layer and a non-oxide dielectric layer as described with reference to the above examples. The structures and functions of unmentioned components may be such so as to already be well understood by one skilled in the art.

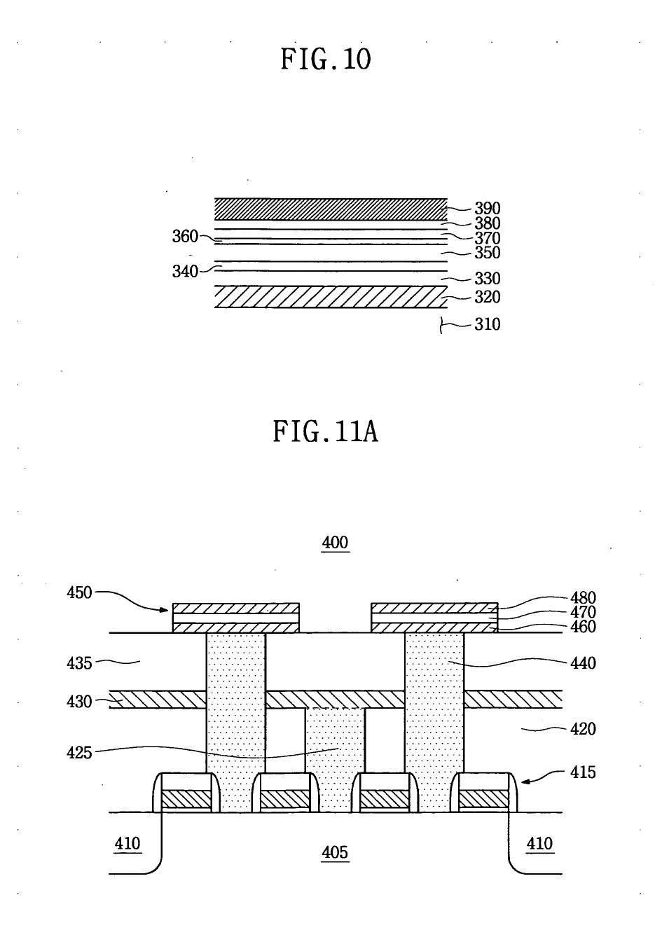

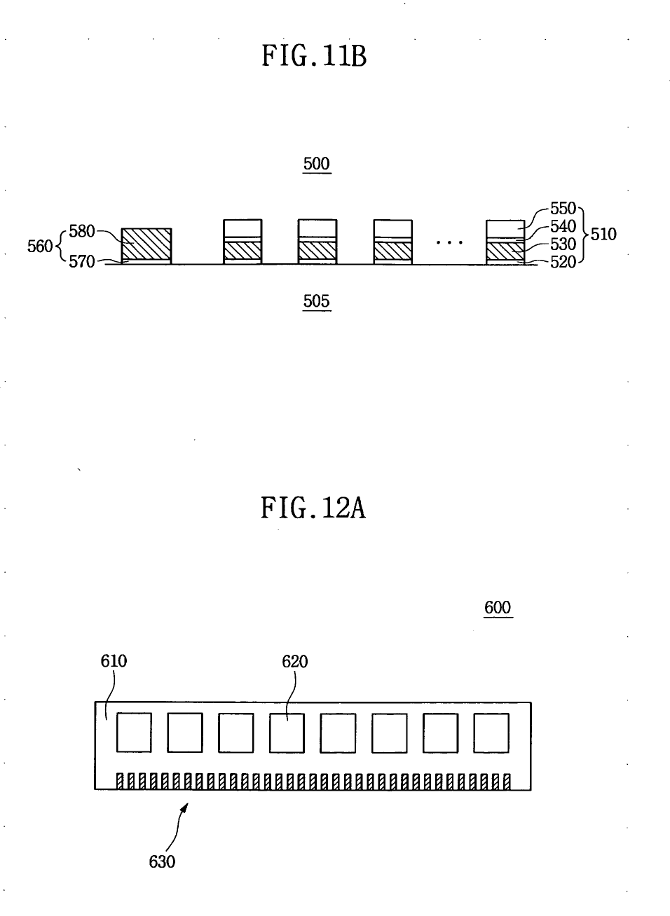

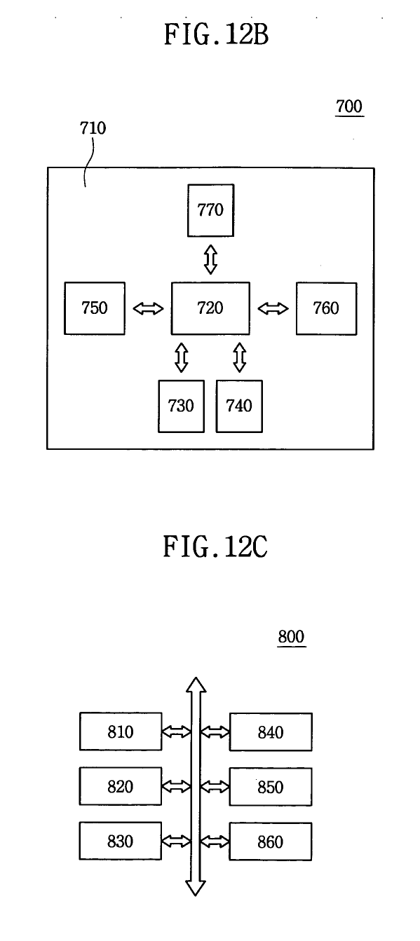

FIG. 12A is a schematic view of a semiconductor module including a semiconductor device having an oxide dielectric layer and a non-oxide dielectric layer according to example embodiments. Referring to FIG. 12A, a semiconductor module 600 according to example embodiments may include a module substrate 610, a plurality of semiconductor devices 620 disposed on the module substrate 610, and module contact terminals 630 disposed in a row on an edge of the module substrate 610 and electrically connected to the semiconductor devices 620. The module substrate 610 may be a printed circuit board (PCB). Both surfaces of the module substrate 610 may be used. Stated more clearly, the semiconductor devices 620 may be disposed on both front and rear surfaces of the module substrate 610. For example, as shown in FIG. 12A, eight semiconductor devices 620 may be arranged on the front surface of the module substrate 610. Also, the semiconductor module 600 may further include an additional semiconductor device configured to control the semiconductor devices 620 or semiconductor packages. Accordingly, one semiconductor module 600 may include a different number of semiconductor devices 620 from the eight semiconductor devices 620 shown in FIG. 12A. At least one of the semiconductor devices 620 may include an oxide dielectric layer and a non-oxide dielectric layer according to the present inventive concept. The module contact terminals 630 may be formed of a metal and may have an oxidation resistance. The module contact terminals 630 may be variously set according to the standards of the semiconductor module 600. Thus, the number of the module contact terminals 630 shown in FIG. 12A may vary.

FIG. 12B is a block diagram of an electronic circuit board including a semiconductor device having an oxide dielectric layer and a non-oxide dielectric layer according to example embodiments. Referring to FIG. 12B, an electronic circuit board 700 according to example embodiments may include a microprocessor 720 disposed on a circuit board 710, a main storage circuit 730 and a supplementary storage circuit 740 configured to communicate with the microprocessor 720, an input signal processing circuit 750 configured to issue a command to the microprocessor 720, an output signal processing circuit 760 configured to receive the command from the microprocessor 720, and a communicating signal processing circuit 770 configured to transmit and receive electric signals to and from other circuit boards. In FIG. 12B, it should be understood that the arrows refer to paths through which the electrical signals may be transmitted.

The microprocessor 720 may receive and process various electric signals, output processing results, and control other components of the electronic circuit board 710. The microprocessor 720 may be interpreted as, for example, a central processing unit (CPU) and/or a main control unit (MCU). The main storage circuit 730 may temporarily store data required by the microprocessor 720, data to be processed, or already processed data. Because the main storage circuit 730 may need a relatively fast response speed, the main storage circuit 730 may include a semiconductor memory. The semiconductor memory may include a cache, an SRAM, a DRAM, an RRAM, or applied semiconductor memories thereof, for example, a utilized RAM, a ferroelectric RAM (FRAM), a fast-cycle RAM, a PRAM, a magnetic RAM (MRAM), or other appropriate semiconductor memories. In addition, the main storage circuit 730 may not be affected by volatility/nonvolatility and may include a RAM. The main storage circuit 730 may include at least one semiconductor device or semiconductor module 600 including an oxide dielectric layer and a non-oxide dielectric layer according to the present inventive concept.

The supplementary storage circuit 740 may be a mass storage device, which may be a nonvolatile semiconductor memory, e.g., a flash memory, or a hard disk drive (HDD) using a magnetic field. Alternatively, the supplementary storage circuit 740 may be a compact disk drive (CDD) using light. As compared with the main storage circuit 730, the supplementary storage circuit 740 may be used to store a relatively large amount of data instead of storing data at a relatively high speed. The supplementary storage circuit 740 may include a nonvolatile memory device irrespective of randomness or non-randomness. The supplementary storage circuit 740 may include at least one semiconductor device or semiconductor module 600 including an oxide dielectric layer and a non-oxide dielectric layer according to the present inventive concept.

The input signal processing circuit 750 may convert an external command into an electric signal or transmit an external electric signal to the microprocessor 720. The external command or electric signal may be an operation command, an electric signal to be processed, or data to be stored. The input signal processing circuit 750 may be, for example, a terminal signal processing circuit configured to process signals received from a keyboard, a mouse, a touch pad, an image recognition apparatus, or various sensors, an image signal processing circuit configured to process an input image signal received from a scanner or a camera, or one of various sensors or input signal interfaces. The input signal processing circuit 750 may include at least one semiconductor device or semiconductor module 600 including an oxide dielectric layer and a non-oxide dielectric layer according to the present inventive concept.

The output signal processing circuit 760 may be a component configured to externally transmit the electric signal processed by the microprocessor 720. For instance, the output signal processing circuit 760 may be a graphic card, an image processor, an optical converter, a beam panel card, or a multifunctional interface circuit. The output signal processing circuit 760 may include at least one semiconductor device or semiconductor module 600 including an oxide dielectric layer and a non-oxide dielectric layer according to the present inventive concept. The communicating signal processing circuit 770 may be a component configured to directly transmit or receive electric signals to and from another electronic system or circuit board without the use of the input signal processing circuit 750 or the output signal processing circuit 760. For example, the communicating signal processing circuit 770 may be a modem of a personal computer (PC), a local area network (LAN) card, or other various interface circuits. The communicating signal processing circuit 770 may include at least one semiconductor device or semiconductor module 600 including an oxide dielectric layer and a non-oxide dielectric layer according to the present inventive concept.

FIG. 12C is a block diagram of an electronic system including a semiconductor device or semiconductor module having an oxide dielectric layer and a non-oxide dielectric layer according to example embodiments. Referring to FIG. 12C, an electronic system 800 according to example embodiments may include a control unit 810, an input unit 820, an output unit 830, and a storage unit 840. The electronic system 800 may further include a communication unit 850 and/or an operation unit 860. The control unit 810 may generally control the electronic system 800 and respective portions. The control unit 810 may be interpreted as a CPU or MCU and may include the electronic circuit board 700 according to example embodiments. Also, the control unit 810 may include at least one semiconductor device or semiconductor module 600 including an oxide dielectric layer and a non-oxide dielectric layer according to the present inventive concept.

The input unit 820 may transmit electric command signals to the control unit 810. The input unit 820 may be an image recognizer or one of various input sensors. The image recognizer may be a keyboard, a keypad, a mouse, a touch pad, or a scanner. The input unit 820 may include at least one semiconductor device or semiconductor module 600 including an oxide dielectric layer and a non-oxide dielectric layer according to the present inventive concept. The output unit 830 may receive electric command signals from the control unit 810 and output processing results of the electronic system 800. The output unit 830 may be a monitor, a printer, a beam irradiator, or one of various mechanical apparatuses. The output unit 830 may include at least one semiconductor device or semiconductor module 600 including an oxide dielectric layer and a non-oxide dielectric layer according to the present inventive concept.

The storage unit 840 may be a component configured to temporarily or permanently store electric signals that will be processed or were already processed by the control unit 810. The storage unit 840 may be physically and electrically connected to or combined with the control unit 810. The storage unit 840 may be a semiconductor memory, a magnetic storage device (e.g., a hard disk), an optical storage device (e.g., a compact disk), or a server with a data storage function. Also, the storage unit 840 may include at least one semiconductor device or semiconductor module 600 including an oxide dielectric layer and a non-oxide dielectric layer according to the present inventive concept.

The communication unit 850 may receive electric command signals from the control unit 810 and transmit or receive electric signals to or from another electronic system. The communication unit 850 may be a modem, a wired transceiver (e.g., a LAN card), a wireless transceiver (e.g. a wireless broadband (WiBro) interface), or an infrared (IR) port. Also, the communication unit 850 may include at least one semiconductor device or semiconductor module 600 including an oxide dielectric layer and a non-oxide dielectric layer according to the present inventive concept. The operation unit 860 may perform physical or mechanical operations in response to a command of the control unit 810. For example, the operation unit 860 may be a component capable of mechanical operations, e.g., a floater, an indicator, or an up/down operator. The electronic system 800 according to the present inventive concept may be a computer, a network server, a networking printer or scanner, a wireless controller, a mobile communication terminal, an exchanger, or other electronic products capable of programmed operations.

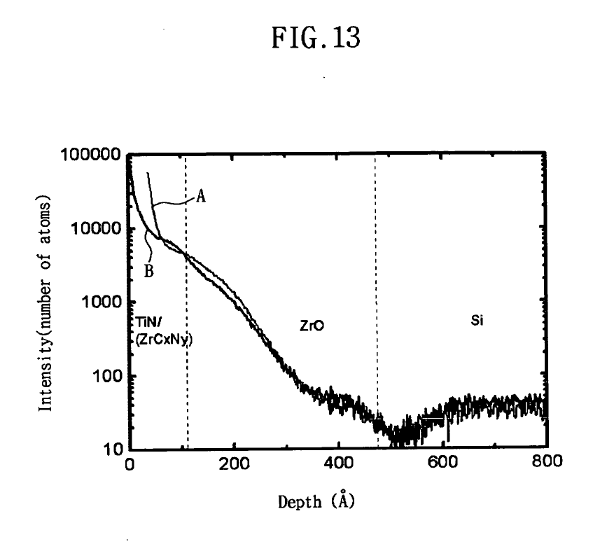

FIG. 13 is a graph illustrating secondary ion mass spectrometry (SIMS) measurements plotted on a log scale of a depth profile of chlorine (Cl) in a capacitor included in a semiconductor device having only an oxide dielectric layer and a depth profile of Cl in a capacitor included in a semiconductor device having both an oxide dielectric layer and a non-oxide dielectric layer according to example embodiments. In FIG. 13, an abscissa (x axis) denotes a depth (Å), and an ordinate (y axis) denotes intensity (the number of atoms). FIG. 13 is a graph showing measurements of a capacitor included in a semiconductor device including a Si lower electrode, a ZrO dielectric layer, and a TiN upper electrode, and the semiconductor device further includes a ZrCN dielectric layer formed on the ZrO dielectric layer. For simplicity, the semiconductor device is compensated such that a grain boundary of the Si lower electrode coincides with a grain boundary of the ZrO dielectric layer. In FIG. 13, curve A shows a case where the ZrCN dielectric layer is not formed, while curve B shows a case where the ZrCN dielectric layer is formed. Referring to FIG. 13, it can be seen that the amount of Cl in the ZrO dielectric layer is smaller in case B than in case A at the same depth.

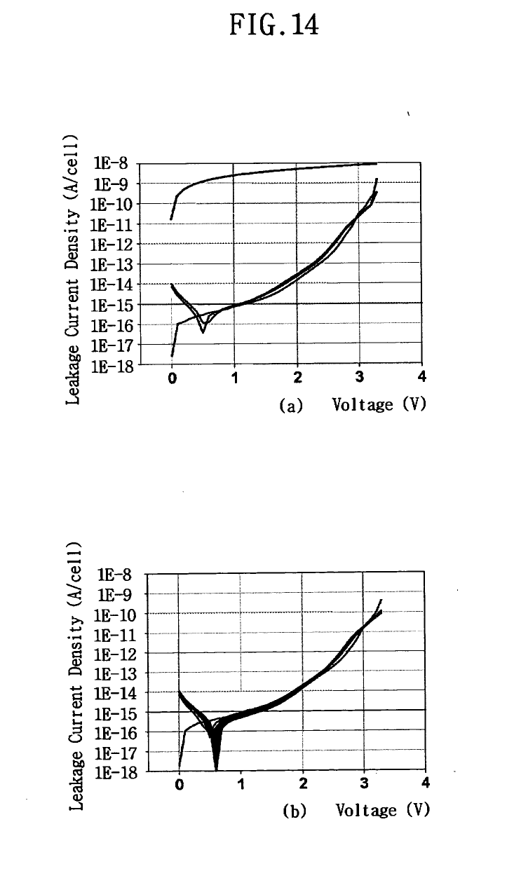

FIGS. 14(a)-(b) illustrate results of a leakage sweep test of a capacitor included in a semiconductor device including only an oxide dielectric layer and a capacitor included in a semiconductor device including both an oxide dielectric layer and a non-oxide dielectric layer according to example embodiments. FIG. 14(a) is a graph showing results of a leakage sweep test of a capacitor included in a semiconductor device including only an oxide dielectric layer. FIG. 14(b) is a graph showing results of a leakage sweep test of a capacitor included in a semiconductor device including both an oxide dielectric layer and a non-oxide dielectric layer according to example embodiments. In (a) and (b) of FIG. 14, an abscissa (x axis) denotes a voltage (V), and an ordinate (y axis) denotes a leakage current density indicated by ampere per cell (A/cell). Also, the uppermost end of each curve reaches 1E-18, while the lowermost end of each curve reaches 1E-8. The leakage sweep test involves repeating an I-V sweep operation until a single cell reaches a predetermined voltage. Referring to (a) and (b) of FIG. 14, the capacitor included in the semiconductor device having only the oxide dielectric layer failed after the sweep operation was repeated only three times, while the capacitor included in the semiconductor device having both the oxide dielectric layer and the non-oxide dielectric layer did not fail even after the sweep operation was repeated fifty times. Therefore, it can be concluded that the capacitor included in the semiconductor device according to the present inventive concept had improved operating characteristics.

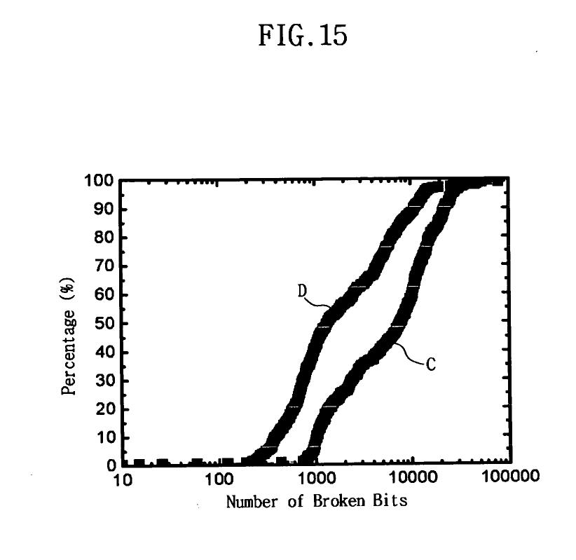

FIG. 15 is a graph showing results of an operation test of a capacitor included in a semiconductor device including only an oxide dielectric layer and a capacitor included in a semiconductor device including both an oxide dielectric layer and a non-oxide dielectric layer according to example embodiments. In FIG. 15, an abscissa (x axis) denotes the number of broken bits, and an ordinate (y axis) denotes a percentage (%). Curve C shows a case where a semiconductor device includes only an oxide dielectric layer, and curve D shows a case where a semiconductor device includes both an oxide dielectric layer and a non-oxide dielectric layer according to the present inventive concept. Referring to FIG. 15, the number of broken bits is greater in case C than in case D at the same percentage.

Herein, it should be understood that the names and functions of components either not mentioned or not shown are such that they may be readily understood in view of the drawings and corresponding descriptions thereof. According to the present inventive concept, in a semiconductor device included in a semiconductor module, an electronic circuit board, or an electronic system, a dielectric layer with relatively stable performance may be formed, thereby improving the performance, durability, and productivity of the semiconductor device.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

1-20. (canceled)

21. A method of fabricating a semiconductor device, comprising:
forming a lower electrode;
forming an oxide dielectric layer on the lower electrode;
forming an upper non-oxide dielectric layer on the oxide dielectric layer; and
forming an upper electrode on the upper non-oxide dielectric layer.

22. The method of claim 21, wherein forming the oxide dielectric layer includes:
supplying a first precursor to the lower electrode to form a unit dielectric layer; and
oxidizing the unit dielectric layer to form a unit oxide dielectric layer,
wherein supplying the first precursor and oxidizing the unit dielectric layer constitute a cycle, the cycle being repeated a plurality of times.

23. The method of claim 22, wherein oxidizing the unit dielectric layer includes supplying an oxidizer to the unit dielectric layer.

24. The method of claim 23, wherein the oxidizer includes at least one selected from the group consisting of ozone (O₃), oxygen (O₂), water vapor (H₂O), and nitrous oxide (N₂O).

25. The method of claim 22, wherein the first precursor includes at least one element selected from the group consisting of lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), cesium (Cs), barium (Ba), lanthanum (La), hafnium (Hf), tantalum (Ta), tungsten (W), rhenium (Re), osmium (Os), iridium (Ir), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), platinum (Pt), gold (Au), mercury (Hg), lead (Pb), bismuth (Bi), polonium (Po), francium (Fr), radium (Ra), actinium (Ac), and silicon (Si).

26. The method of claim 21, wherein forming the upper non-oxide dielectric layer includes supplying a second precursor to the oxide dielectric layer to form a unit non-oxide dielectric layer, wherein supplying the second precursor is repeated a plurality of times.

27. The method of claim 26, wherein the second precursor includes at least one element selected from the group consisting of hydrogen (H), boron (B), carbon (C), nitrogen (N), fluorine (F), chlorine (Cl), and iodine (I).

28. The method of claim 26, further comprising:
annealing the upper non-oxide dielectric layer.

29. The method of claim 21, further comprising:
forming a lower non-oxide dielectric layer between the lower electrode and the oxide dielectric layer.

30. A method of fabricating a semiconductor device, comprising:
loading a wafer into a reaction chamber;
performing a first process to form an oxide dielectric layer on the wafer; and
performing a second process to form a non-oxide dielectric layer on the oxide dielectric layer,
wherein performing the first process includes:
supplying a first precursor to the reaction chamber to form a first unit dielectric layer on the wafer;
supplying a first purge gas to the reaction chamber to discharge any remaining first precursor from the reaction chamber;
supplying an oxidizer to the reaction chamber to convert the first unit dielectric layer into a unit oxide dielectric layer; and
supplying a second purge gas to the reaction chamber to discharge any remaining oxidizer from the reaction chamber,
wherein supplying the first precursor, supplying the first purge gas, supplying the oxidizer, and supplying the second purge gas constitute a first cycle, the first cycle being repeated a plurality of times, and
wherein performing the second process includes:
supplying a second precursor to the reaction chamber to form a second unit dielectric layer on the oxide dielectric layer; and
supplying a third purge gas to the reaction chamber to discharge any remaining second precursor from the reaction chamber,
wherein supplying the second precursor and supplying the third purge gas constitute a second cycle, the second cycle being repeated a plurality of times.

31. The method of claim 30, further comprising:
annealing the non-oxide dielectric layer.

32. The method of claim 30, wherein the first precursor includes at least one element selected from the group consisting of lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), cesium (Cs), barium (Ba), lanthanum (La), hafnium (Hf), tantalum (Ta), tungsten (W), rhenium (Re), osmium (Os), iridium (Ir), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), platinum (Pt), gold (Au), mercury (Hg), lead (Pb), bismuth (Bi), polonium (Po), francium (Fr), radium (Ra), actinium (Ac), and silicon (Si).

33. The method of claim 30, wherein the second precursor includes at least one element selected from the group consisting of hydrogen (H), boron (B), carbon (C), nitrogen (N), fluorine (F), chlorine (CO, and iodine (I).

34. The method of claim 30, wherein the oxidizer includes at least one selected from the group consisting of ozone (O₃), oxygen (O₂), water vapor (H₂O), and nitrous oxide (N₂O).

35. A method of fabricating a semiconductor device, comprising:
forming a lowermost dielectric layer;
forming a lower dielectric layer on the lowermost dielectric layer;
forming a main dielectric layer on the lower dielectric layer;
forming a first upper dielectric layer on the main dielectric layer;
forming a second upper dielectric layer on the first upper dielectric layer; and
forming an upper electrode on the second upper dielectric layer,
wherein each of the lowermost dielectric layer, the lower dielectric layer, the first upper dielectric layer, and the second upper dielectric layer includes a first metal.

36. The method of claim 35, wherein the main dielectric layer includes a second metal different from the first metal.

37. The method of claim 35, wherein each of the lower dielectric layer, the main dielectric layer, the first upper dielectric layer, and the second upper dielectric layer includes a first material and oxygen, and the uppermost dielectric layer is free from the first material.

38. The method of claim 37, wherein the first material includes at least one element selected from the group consisting of lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), cesium (Cs), barium (Ba), lanthanum (La), hafnium (Hf), tantalum (Ta), tungsten (W), rhenium (Re), osmium (Os), iridium (Ir), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), platinum (Pt), gold (Au), mercury (Hg), lead (Pb), bismuth (Bi), polonium (Po), francium (Fr), radium (Ra), actinium (Ac), and silicon (Si).

39. The method of claim 35, wherein each of the lowermost dielectric layer, the lower dielectric layer, the first upper dielectric layer, the second upper dielectric layer, and the uppermost dielectric layer includes a second material, and the main dielectric layer is free from the second material.

40. The method of claim 39, wherein the second material includes at least one element selected from the group consisting of lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), cesium (Cs), barium (Ba), lanthanum (La), hafnium (Hf), tantalum (Ta), tungsten (W), rhenium (Re), osmium (Os), iridium (Ir), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), platinum (Pt), gold (Au), mercury (Hg), lead (Pb), bismuth (Bi), polonium (Po), francium (Fr), radium (Ra), actinium (Ac), and silicon (Si).
